(19) United States
(12) Patent Application Publication
(10) Pub. No.: US 2018/0073168 A1
(43) Pub. Date: Mar. 15, 2018

(54) ENERGY HARVESTERS, ENERGY STORAGE, AND RELATED SYSTEMS AND METHODS

(71) Applicant: The North Face Apparel Corp., Wilmington, DE (US)

(72) Inventors: Justin Lee Gladish, Oakland, CA (US); Mary-Ellen Smith, San Francisco, CA (US)

(73) Assignee: The North Face Apparel Corp., Wilmington, DE (US)

(21) Appl. No.: 15/557,779

(22) PCT Filed: Mar. 14, 2016
(86) PCT No.: PCT/US16/22353

§ 371 Date: Sep. 12, 2017

Related U.S. Application Data
(60) Provisional application No. 62/133,203, filed on Mar. 13, 2015.

(51) Int. Cl. D03D 1/00; D03D 7/00; H01L 31/042; H02J 1/00; H02J 7/00; H01R 13/03; H02J 50/10

(52) U.S. Cl. CPC D03D 1/0088; D03D 1/0076; D03D 7/00; H01L 31/042; F21V 33/0008; H02J 7/0068; H01R 13/035; H02J 50/10; D10B 2403/021; H02J 1/00

(57) ABSTRACT

A textile construct has a first fiber configured to convert one or more forms of ambient energy to an electrical potential. A plurality of second fibers are mechanically coupled with the first fiber to define a textile. An electrical connector operatively couples to the first fiber to convey the electrical potential to a complementarily configured electrical device. An energy-harvesting platform can have such a textile construct. The complementarily configured electrical device can be a platform accessory.

### BACKGROUND

This application, and the innovations and related subject matter disclosed herein (collectively referred to as the “disclosure”) concern energy harvesters, energy storage, systems configured to harvest energy and/or to store energy in a useable form, and related methods. More particularly, but not exclusively, disclosed harvesters can be implemented in woven and non-woven (e.g., knitted, felt, etc.) textiles. In particular embodiments, such textiles can be used in addition to, or can replace, conventional textiles in familiar products, including, for example, footwear, clothing, sporting goods, luggage, canopies, and other panelized textiles, to convert otherwise wasted or unusable ambient energy to one or more useable forms of energy. Certain examples of systems incorporating such innovative textiles are described in relation to athletic apparel, sporting goods, and/or footwear, though the innovative principles disclosed herein may be implemented in a variety of other embodiments, as will be recognized and appreciated by those of ordinary skill in the art following a review of this disclosure.

A major limitation on the use of personal electronic devices, including for example, smart phones, has been a lack of available power sources. For example, batteries traditionally suffer limited capacity and thus limited usage time based on size and weight limitations imposed by consumer mobility requirements. Portable batteries have been employed in situations where mobile power is required. Battery options were preceded by gas powered generators. Batteries are heavy while generators required chemical fuel inputs. Batteries also fail, requiring replacements over time. Replacing batteries can become costly, time consuming, and environmentally unsustainable.

Nonetheless, demand for power continues to increase. As demand for power and electricity has increased the demand for mobile power has increased. Parallel to and in tension with this, the demand for green and renewable energy sources has increased.

An effective approach for overcoming limited battery life is to recharge a battery using energy converted from available environmental energy. Many environmental (also referred to as “ambient”) sources of energy are available: solar energy, wind energy, thermal energy, hydroelectricity, human or animal movement, and mechanical (e.g., kinetic or mechanical potential) energy. In context of apparel and fabric applications, solar and mechanical (wind, rain, movement) energy is typically available, but conventional harvesters of such energy have been inadequate for consumer goods.

Conventional energy harvesters have come in a variety of different forms. Photovoltaic solar cells have improved from stiff rigid solar panels to panels that allow flexibility by segmenting the panel into smaller panels. Currently, research is moving toward organic photovoltaic cells which are believed to be more sustainable than earlier photovoltaic cells. Some previous energy harvesters have been used to power microprocessors, sensors, street lights, parking meters, LED's, flashlights, radios, etc. For larger electronic applications, many products incorporate solar panels. Because it is difficult to increase the efficiency of solar panels, many solar panels are often sold unbranded and their performance is unknown.

Photovoltaic panels have been affixed to or deposited onto textile substrates and incorporated in backpacks, apparel and tents. However, previously proposed photovoltaic panels cover large areas and their unsightly appearance limit aesthetic variability and appeal of consumer goods, including apparel, backpacks and tents. Other desirable features of conventional textiles are also lost when such panels have been applied, for example, flexibility, breathability, and even the ability to launder the textile. As well, incorporating photovoltaic panels into packs, tents, and garments may also require additional sewing and laundering techniques, adding to total cost of ownership and deterring the adoption of photovoltaic energy harvesters in textiles.

Wind and rain energy harvesters have also been proposed. However, such harvesters have been difficult to incorporate into fabric and apparel. For example, wind turbines driven by wind can be used to power a generator, converting mechanical energy to electrical energy. However, such turbines are not easily incorporated into or onto textiles usable for consumer-focused products, such as garments, footwear, luggage, etc. Manufacturing of conventional solar cells can be expensive and most are still rigid and inefficient, presenting design limitations in relation to use in certain product categories (e.g., apparel, footwear, headwear, and “gear,” such as, for example, sporting goods and luggage).

Thus, a need remains for energy harvesters that can provide a continuous source of renewable energy that is both efficient and cost effective. There also exists a need to improve the efficiency and the application of energy harvesting techniques for mobile platforms. A further need remains for energy harvesters exhibiting one or more characteristics similar to conventional textiles, such as wash durability, flexibility, easy integration, bulkiness (and lack thereof), lifespan, cost, general aesthetics, and ease of manufacturing, while providing efficient energy conversion and useful output power.

### SUMMARY

The innovations disclosed herein overcome many problems in the prior art and address one or more of the aforementioned or other needs. In some respects, the innovations disclosed herein are directed to energy harvesters, energy storage, systems configured to harvest energy and/or to store energy in a useable form, and related methods. In some embodiments, such energy harvesters can be incorporated into textile structures, such as, for example, individual fibers. In other embodiments, such energy harvesters can be formed from complementary fibers combined into a woven, a knit, or a non-woven (e.g., an entangled or matted) textile structure. Such textile structures can, in turn, be incorporated into familiar forms to provide an enhanced user experience, with footwear, apparel, head wear, luggage, sporting goods, being particular examples of such familiar forms. As but one particular example, a garment incorporating an energy-harvesting textile as described herein can provide extended and/or continuous off-the-grid use of an electronic device by converting available ambient energy to a useful form of energy suitable for powering the electronic device.

According to other aspects, energy harvesting textiles can provide an efficient, comfortable, and safe platform for providing power to and being compatible with a variety of electricity-consuming devices. As but one example of such a platform, a garment incorporating an energy-harvesting textile can include a physical and/or a near-field electrical connector suitable for transferring harvested electrical energy to an accessory device, e.g., a light, a radio transceiver, a smartphone, a computing table, a

GPS device, a biologic or other type of sensor, and any of a variety of other electricity-consuming devices now known or hereafter developed. As used herein, the term “near-field electrical connector” means a wireless coupler suitable to transmit or to receive electro-magnetic energy in a form useable to power an electrical device. As used herein, a near-field electrical connector is distinguished from a radio transmitter or receiver that transmits or receives signals carrying energy.

The foregoing and other features and advantages will become more apparent from the following detailed description, which proceeds with reference to the accompanying drawings.

### BRIEF DESCRIPTION OF THE DRAWINGS

Unless specified otherwise, the accompanying drawings illustrate aspects of the innovative subject matter described herein. Referring to the drawings, wherein like numerals refer to like parts throughout the several views and this specification, several embodiments of presently disclosed principles are illustrated by way of example, and not by way of limitation, wherein:

FIG. 1 shows an example of a spacer mesh incorporating an energy harvesting fiber;

FIG. 2A shows an example of a conductive fiber or yarn;

FIG. 2B shows an example of a woven textile incorporating an electrical conductor;

FIG. 2C shows an example of a knitted textile incorporating an electrical conductor;

FIG. 3A shows an energy platform embodied as an item of footwear;

FIG. 3B shows the energy platform depicted in FIG. 3A in combination with a compatible accessory embodied as a lighting element of the type depicted in FIG. 4;

FIG. 4 depicts an accessory embodied as a lighting element;

FIG. 5 shows an energy platform embodied as a garment, and more particularly as an item of outerwear;

FIGS. 5A, 5B, 5C, and 5D show energy platforms embodied as various garments;

FIG. 6 shows the energy platform depicted in FIG. 5 in combination with a compatible accessory;

FIG. 7A shows an energy platform embodied as a backpack;

FIG. 7B shows the energy platform shown in FIG. 7A in combination with a compatible accessory;

FIGS. 8A and 8B show an energy platform embodied as footwear combined with several accessories embodied as pressure sensors, smart materials, and controllers;

FIG. 8C shows a pair of energy platforms, each embodied as a glove in combination with accessories similar to those shown in FIGS. 8A and 8B.

FIGS. 9A, 9B, and 9C show an energy platform embodied as footwear combined with several accessories embodied as pressure sensors, smart materials, and controllers;

FIG. 10 shows an energy platform embodied as footwear combined with several accessories embodied as pressure sensors, smart materials, and controllers;

FIG. 11 shows a schematic illustration of a computing environment suitable for implementing one or more disclosed technology examples.

### DETAILED DESCRIPTION

The following describes various innovative principles related to energy harvesters, energy storage, systems configured to harvest energy and/or to store energy in a useable form, and related methods by way of reference to specific examples of energy harvesting fibers and textiles, and apparatus and systems incorporating such fibers and textiles, and more particularly but not exclusively, to particular embodiments of garments, footwear, sporting goods, and luggage incorporating such fibers and textiles, as well as specific embodiments of electrical and electronic accessories suitable for use with one or more energy harvesters. Nonetheless, one or more of the disclosed principles can be incorporated in various other devices, systems or methods to achieve any of a variety of corresponding desired characteristics. Techniques and systems described in relation to particular configurations, applications, or uses, are merely examples of techniques and systems incorporating one or more of the innovative principles disclosed herein and are used to illustrate one or more innovative aspects of the disclosed principles.

Thus, devices, systems and methods having attributes that are different from those specific examples discussed herein can embody one or more of the innovative principles, and can be used in applications not described herein in detail. Accordingly, such alternative embodiments also fall within the scope of this disclosure.

### Overview

Disclosed, fiber-based energy harvesters can be flexible and light-weight, and can be formed (e.g., woven, knitted, entangled, etc.) into multiple configurations and many functional structures without disturbing or departing from currently known and well-understood textile forming processes. Several examples of textile forming processes are described in U.S. Patent Application No. 61/991,293 and related International Patent Application No. PCT/US2015/027975, the contents of which are hereby incorporated in their entirety as if recited in full, for all purposes.

For example, some disclosed textile structures, whether knitted, woven and/or entangled, can incorporate one or more energy harvesting fibers. Such fibers can include one or more of a piezo-electric fiber configured to convert mechanical energy to an electric current by way of movement of the fiber, a photovoltaic fiber configured to convert light energy to an electric current, and/or a fiber having combined piezo-electric and photovoltaic properties such that it is configured to convert mechanical energy as well as incident light to electrical current. Some disclosed textile structures include a hybrid structure of conventional fibers with energy harvesting fibers to provide a textile having hybrid energy harvesting and conventional characteristics arising from the combined use of the conventional and energy harvesting fibers. In specific embodiments, some disclosed textile structures can include electrical conductors (e.g., electrically conductive fibers, filaments, depositions, e.g., printed inks, etc.) arranged to convey harvested electrical energy to a common plane, buss, circuit, connector or other device for further conveying electrical current to an electrical or electronic accessory, and/or to a battery or other electrical storage device (e.g., a capacitor). Such interconnections of textile structures can be in parallel or in series, e.g., to increase voltage potential or electrical current arising from the interconnected textile structures.

Energy harvesters of the type briefly described above can be incorporated in one or more textile-based devices, such as footwear, apparel, head wear, luggage, sporting goods, etc. In turn, such a textile-based device can be used as an energy source compatible with a variety of interoperable accessories, for example through a proprietary or an open-source connector. Such connectors can be conductive (i.e., configured to physically couple first and second portions of an electrical circuit to each other to permit an electrical current to flow from one of the portions to the other of the portions) or inductive (i.e., configured couple first and second portions of an electrical circuit to each other by way of, for example, a magnetic field, to induce an electrical current in one portion in correspondence with another electrical current passing through the other portion). Such an interoperable accessory (sometimes referred to as a “platform accessory”) can generally be any electrical device, for example a smartphone, a sensor, a transmitter, a receiver, a location beacon, a GPS device, a light, a heater, a battery, a smart material, a watch, a headphone, etc.

### EXAMPLE 1

### Textile-Based Energy Harvesters

To date, much research into flexible energy harvesters for textile and/or fabric applications has been reported. For example, Sphelar Power Corporation has created small spherical solar cells woven into a piece of fabric. Such fabric is made of wafer-thin solar cells woven together. So-called Power Felt can convert a temperature differential into electrical current. In Power Felt, juxtaposed layers of carbon nanotubes and plastic insulation can convert any temperature differential to electrical current. Parasol (http://www.ncmbc.us/product-providers/documents/ParaSol_Enertex_Technology_Farahi.pdf) uses fibers that utilize waveguide assisted energy harvesting to gather and concentrate incident light onto relatively smaller areas of photovoltaic cells.

Current research continues at many domestic and international universities and institutions research energy harvesting techniques. For many, the focus has been to incorporate solar harvesting into a textile fiber.

Two European organizations have focused research on textile based photovoltaic novel fibers. Dephotex is a European collaborative research project aiming at the development of flexible photovoltaic textiles to power wearable consumer goods as well as on/off grid systems (http://www.dephotex.com/). Powerweave is a project focused on the Development of Textiles for Electrical Energy Generation and Storage supported by the European Commission through the Seventh Framework Program for research and technological development of advanced textiles for the energy and environmental protection markets. The objective of the project is based on the development of a fabric to generate (10 W/m2) and store (10 Wh/m2) energy within a totally fibrous matrix (http://www.powerweave.eu/).

A silicon-based optical fiber with solar-cell capabilities has been developed at Penn State University. The fiber allows the possibility of weaving together solar-cell silicon wires to create flexible, curved, or twisted solar fabrics.

In addition to all these developments, University of Bolton has created “A novel low cost technology has been developed that integrates piezoelectric polymer substrate and organic photovoltaic coating system to create 3-D fibre structures capable of harvesting energy from nature, including sun, rain, wind, wave and tide. They are flexible and can be incorporated in textiles for a wide variety of applications on earth, underwater and possibly space.” (http://www.idtechex.com/events/presentations/smart-functional-materials-for-energy-harvesting-from-laboratory-to-commercialisation-006028.asp). The fiber combines flexible photovoltaic materials, with flexible piezoelectric fibres. This fiber generates electricity by harvesting solar energy as well as harvesting energy from movement, rain, and wind. Other fiber- and/or textile-based energy harvesters have been developed at University of Bolton. Such harvesters are described, for example, in U.S. Publication Nos. 2013/0257156, 2014/0145562, and 2014/0331778, each of which is hereby incorporated in its entirety as if reproduced in full, for all purposes.

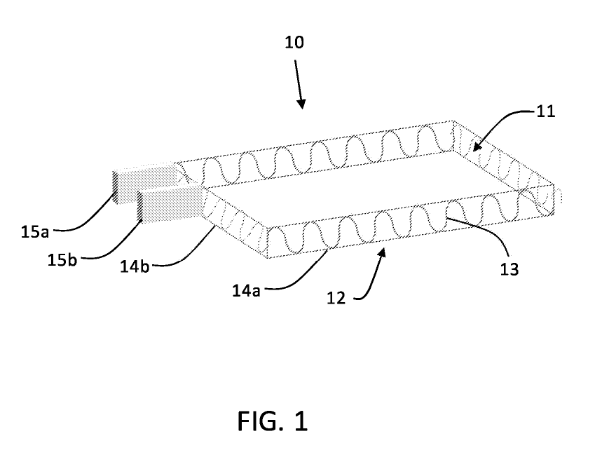

In some embodiments, as illustrated in FIG. 1, a spacer mesh 10 having a first textile face 11 and an opposed second textile face 12 can incorporate one or more piezo-electric fibers 13 extending there between. If the spacer mesh is compressed (e.g., the faces 11, 12 are urged toward each other), the piezo-electric fiber can physically deform and generate an electrical current and/or an electrical potential. The spacer mesh can be configured to collect the electrical current/electrical potential from each piezo-electric fiber 13 along one or more edges 14a, 14b thereof, and to convey such current/potential to electrodes 15a, 15b configured to electrically couple the spacer mesh to another textile structure and/or to an electrical circuit, or portion thereof.

Other arrangements suitable to convey electrical power are possible. For example, other woven, knit, or non-woven textiles can incorporate a piezo-electric (PE) fiber, a photovoltaic (PV) fiber, or a hybrid PE/PV fiber, or other fiber suitable for converting ambient energy to useable electrical energy. As but one example, at least one warp and/or weft yarn of a woven textile can comprise such an energy-harvesting fiber to form an energy-harvesting textile. The energy harvesting textile, in turn, can incorporate electrodes in a fashion similar to the electrodes 15a, 15b schematically illustrated in FIG. 1 to convey harvested electrical energy to a circuit coupled to the textile, as through a disclosed connector.

A position of a fiber suitable for converting ambient energy to useable electrical energy can be selected within a given textile, a PV fiber can be exposed to a region anticipated to be exposed to light during use. For example, a textile panel can be oriented to expose a PE fiber to a desired amount of movement (e.g., on an upper of an item of footwear in an area exposed to flexing throughout a user's stride).

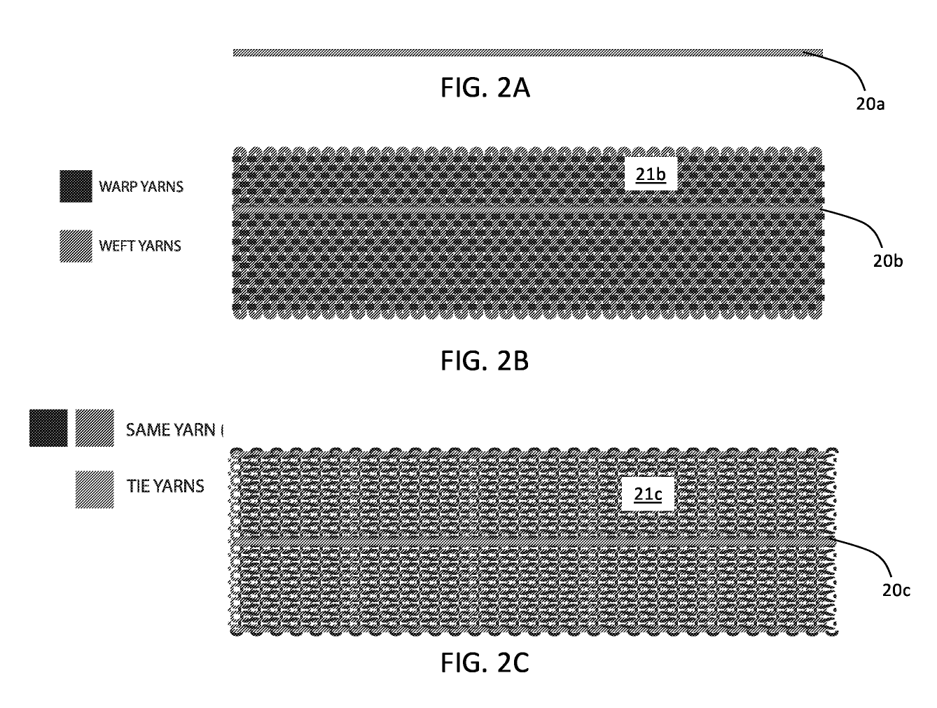

FIGS. 2A, 2B and 2C illustrate examples of electrically conductive textile structures suitable for conveying an electrical current between an energy harvester of a type described above. In FIG. 2A, an electrically conductive fiber or yarn 20a can be incorporated in a textile panel (e.g., as depicted in FIG. 1) in an arrangement suitable for the fiber 20a to electrically couple to one of the electrodes 15a, 15b. Alternatively, a deposition layer of an electrical conductor 20b, 20c can be applied to a surface of a textile panel, as shown in FIGS. 2B (woven textile) and 2C (knit textile), respectively. In some embodiments, the deposition layer can include an electrically conductive ink suitable for textile printing. In addition, or as an alternative, the deposition layer can include one or more electrical devices (e.g., resistors, capacitors, inductors, transistors, memory cells, processors, operable circuits, electrically operative materials, etc.) to form a smart textile and/or to form a textile panel that can be interconnected with one or more other textile panels and/or a more conventional printed circuit board.

Electrodes 15a, 15b can be coupled to a first inductor coil (not shown). An adjacent textile panel or accessory can include a complementary second inductor coil (not shown), and a magnetic field induced by an electric current passing through the first coil can induce a corresponding second electrical current in the second inductor coil. The second electrical current can power an electrical circuit in the adjacent textile or accessory. Such a textile or accessory can include one or more electrical devices now known or hereafter developed.

### EXAMPLE 2

### Energy Platform

An operable device can incorporate energy harvesting fibers and/or textiles to form an energy platform to which interoperable accessories can couple and from which they can receive power (e.g., in the form of electrical current). For example, a PE-based spacer mesh can be incorporated in a sole unit of an item of footwear. As used herein, a sole unit can constitute an insole, a midsole, an outsole, or a combination thereof, of an item of footwear. An interoperable accessory can couple, directly or indirectly, to the power-output of the spacer mesh to receive power from the spacer mesh for operating the accessory. Such an accessory can be any of a variety of accessories as described herein.

As but several other examples of many contemplated examples, an energy platform can include a backpack, a canopy or tent, other outdoor gear, and/or apparel. As will be appreciated, some energy platforms are better suited to incorporate a PE-based textile for energy harvesting and some are better suited for hybrid PE/PV-based or solely PV-based textiles according to a likely use to which the platform will be put. For example, a sole unit likely will be exposed to many cycles of compression/decompression loading, and will likely not be exposed to meaningful amounts of incident light energy. Accordingly, an energy platform in the form of a sole unit configuration could suitably rely on a PE-based textile. On the other hand, a sail, intended to be taught and not allowed to waft, will be exposed to primarily light energy and only moderate amounts of mechanical deformation. Accordingly, an energy platform in the form of a sail might suitably rely primarily on a PV-based textile. As yet another example, cycling pants could be exposed to substantial light energy as well as physical deformation. Thus, an energy platform in the form of cycling pants could suitably rely on a hybrid PE/PV-based textile.

Regardless of the specific embodiment of a given energy platform, accessories complementary to, or interoperable with, the given platform are possible. For example, batteries (e.g., rechargeable and/or printed), deposited circuits (e.g., printed conductive inks, deposited or printed electronics, such as for example LED's, sensors), wireless charging, and gesture controllers, etc. can operatively couple to a given energy platform to provide a fully functional and autonomous user experience.

Moreover, as electronics evolve, e.g., based on software upgrades and new applications, disclosed energy platforms can be retained to provide an expanded user experience simply by substituting a new accessory for an older accessory. Such a modular arrangement of interoperable components permits adoption and blending of old and new charging technologies across platforms. As but one example, Microsoft's AutoCharge lamp can be incorporated into backpacks and apparel. In this case, a sensor can detect a charge power level of, for example, a phone battery when the phone enters a room. Following detection, a direct and focused beam of light can be directed to a panel of PV-based textile to induce an electrical current that, in turn, can charge a battery or supply power to an accessory.

### EXAMPLE 3

### Footwear

As indicated above, a sole unit for footwear can incorporate a spacer mesh and harvest energy from an impact of walking and running (compaction and expansion of the spacer mesh). Energy can also be harvested by the flexing of the spacer mesh. Such flexing can happen across the entire foot bed, e.g., from the heal to the toe, in some embodiments. The mesh can also be placed into specific areas, such as high impact areas of the heel and forefoot.

The mesh, using piezoelectric fibers, can be durable enough to last a lifetime of the footwear. As well, some sole units can be removed and placed into new footwear.

Incorporating an energy harvesting device into footwear allows many different options for development that are much more efficient than before. Because energy is continuously provided the size of a battery currently used to power a given electrical device can be reduced, removing an existing impediment to the incorporation of electronics into textiles. Printed or deposited circuits can provide additional options to reduce weight.

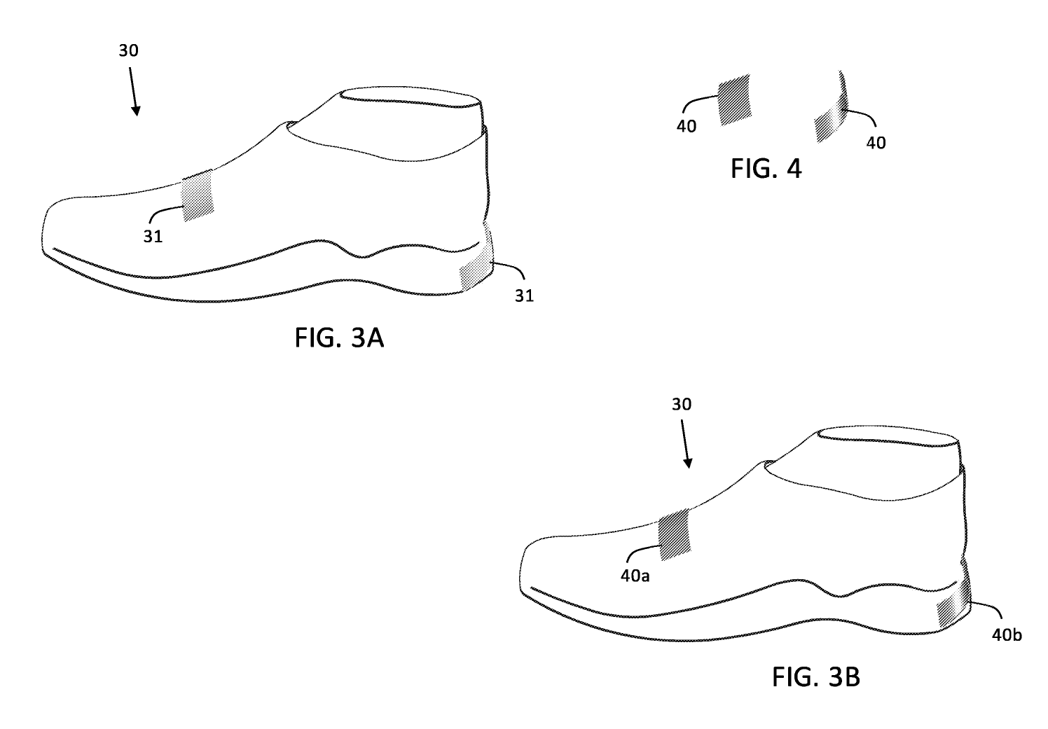

Printable, conductive inks, such as graphene, can be placed in various areas around the sole unit and/or a corresponding upper. As shown in FIG. 3A, an item of footwear 30 can have an electrical connector 31.

Throughout this disclosure, it is to be understood that the term electrical connector includes conductive connectors as well as inductive or “near-field” connectors for coupling electrical circuit portions to each other and to urge an electrical current through a selected circuit portion.

In some instances, the electrical connector 31 is positioned internally of the footwear, externally of the footwear, or embedded in, for example, an upper of the footwear. The connector 31 can include or be formed as a deposition layer. As shown in FIG. 4, an accessory unit 40 can include one or more lights. As but one illustrative example of coupling an accessory to an energy platform, the lights 40 can be affixed to or otherwise coupled to the footwear item 30 in an operable relationship relative to the connectors 31 (FIG. 3A). The accessories can receive electrical energy suitable for powering the accessories, as depicted by the illuminated lights 40a, 40b in FIG. 3B.

In addition to a sole unit incorporating a PE-based textile, footwear uppers can incorporate PE/PV hybrid textiles (or, as desired, PE- or PV-based textiles). A textile used to form the upper can include a knit or a woven material incorporating, for example, the hybrid PE/PV fiber. Accordingly, an upper incorporating an energy harvesting textile can provide additional energy harvesting from the footwear as compared to footwear incorporating only an energy harvesting sole unit. For example, an upper can often be exposed to sunlight and indoor lighting, as well as movement from flexion throughout a user's gait.

Some energy harvesting textiles are flexible enough to allow the footwear upper to be constructed in a single piece using various selected knitting and/or weaving techniques. Components and electrical connections can be added after the footwear has been assembled. Alternatively, some contemplated accessories, e.g., sensors and electronic components, can be incorporated in one or more layers of a fiber during extrusion (multi-layered core sheath).

As will be understood, energy platforms incorporating textile-based energy harvesters can be further optimized with the use of fiber batteries, fiber energy harvesters, and fiber sensors in the yarns and fibers. Moreover, yarns and fibers can be aligned in advanced knitting and weaving machines to allow, for example, a one-piece footwear upper to be constructed with specific yarns/fibers of energy harvesting, sensors, and/or batteries at specific (e.g., desired) positions. Similarly, in the case of forcespinning, e.g., one-piece footwear uppers, these fibers, fiber meshes, fiber sensors, fiber batteries, electronic components and other energy harvesters can be placed in the forcespinning process before, after, or during the forcespinning of fibers onto the shoe last. In the case of forcespinning onto a model or mold in the case of a one-piece garment of garment/footwear component, these components can also be incorporated. Aspects of forcespinning are disclosed in International Patent Application No. PCT/US14/045484, the contents of which are hereby incorporated by reference in full, for all purposes, and reproduced in the accompanying Annex.

### EXAMPLE 4

### Electrical Conductors

Although conductive wires or other common circuit elements can be used to collect and convey electrical current from the mesh, such combinations can become bulky and cumbersome in context of selected energy platforms (e.g., footwear).

Accordingly, some embodiments incorporate smart conduction textiles and fibers, as described in relation to FIGS. 2A, 2B and 2C. Conductive fibers can include synthetic/natural fibers that have metallic particles deposited on them, metallic wires that may or may not be wrapped by a synthetic/natural fiber, polymers with conductive particles inside. To reduce the space as well as reducing the use of wires and metals, deposition layers, including electrically conductive inks can be used. Common suppliers of such deposition materials include T-ink, Nagase, and DuPont.

In some embodiments, PE-based textiles can be encapsulated so as to be less susceptible to damage by water or other liquids. An electrically conductive printed ink can connect to two leads 15a, 15b on the spacer mesh. The conductive inks can in turn connect to a rechargeable battery that is on or in the footwear.

### EXAMPLE 5

### Batteries

Disclosed batteries can be of any selected power capacity or size. Some contemplated batteries comprise juxtaposed layers of deposited materials on textiles suitable for forming a battery in combination. Other batteries incorporate fiber-based batteries for storage. In some instances, energy harvesting fibers can be woven, knit, or otherwise joined to form a textile structure in combination with the battery fibers. Such batteries are believed to be well suited for footwear (and other energy platforms) when taking into account competing requirements of size, weight, and charge-holding capacity.

In any event, contemplated batteries can be detachable or fully integrated in the energy platform, e.g., footwear. In the case of a detachable battery, different approaches for attaching the battery to the footwear are contemplated, including lacing systems, magnets, hook-and-loop fasteners, snaps, zipper pouches, and other known fasteners. As will be appreciated, such a battery can have an irregular shape to blend in with the footwear and/or to provide a desired design aesthetic (e.g., to blend in and provide an incognito appearance).

A given battery may have one or more charging ports (e.g., a USB-C port) to charge various accessories across a variety of electrical current ratings, and/or to charge the battery from a secondary source (e.g., a conventional wall outlet). The battery may be operably coupled directly or indirectly to any of a variety of accessories as described more fully below.

### EXAMPLE 6

### Garments

Energy harvesting textiles incorporating PE-, PV-, and hybrid PE/PV-based fibers can form one or more panels incorporated into a variety of garments. Additionally, electrically conductive fibers and/or deposition layers, as along a seam, with a waterproof seam being but one particular example, can collect and convey electrical current generated by the harvester. One or more batteries, connectors, and/or accessories can be operatively coupled to the harvester, as described in other examples herein.

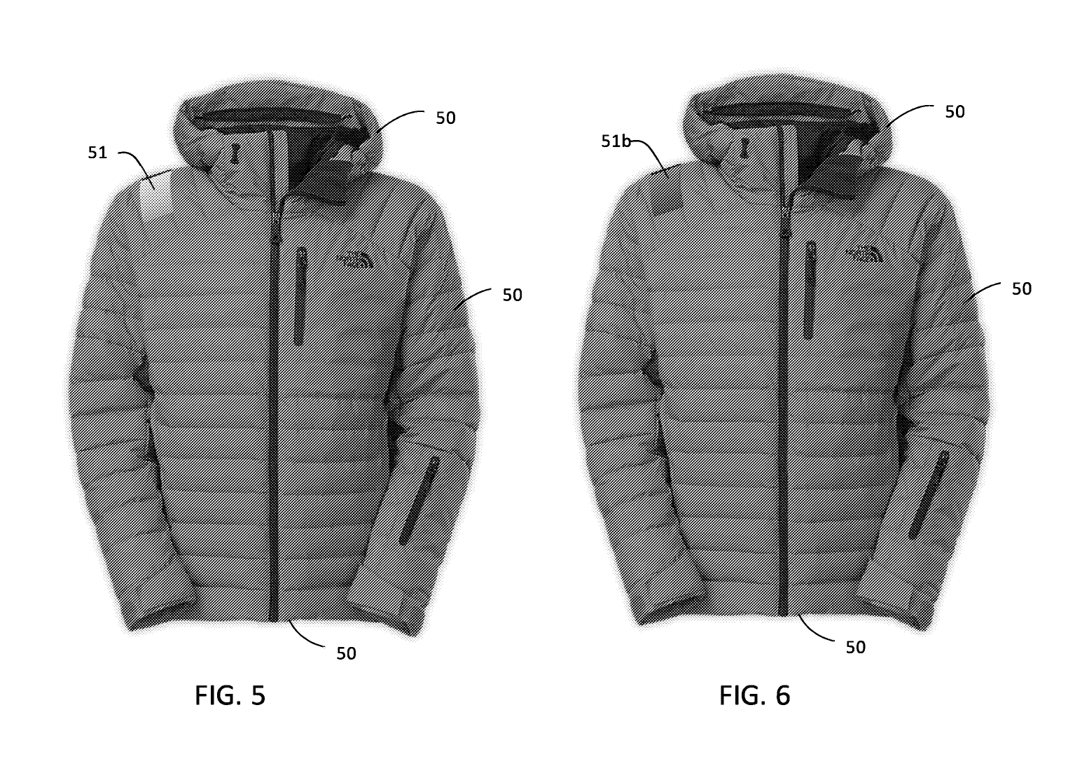

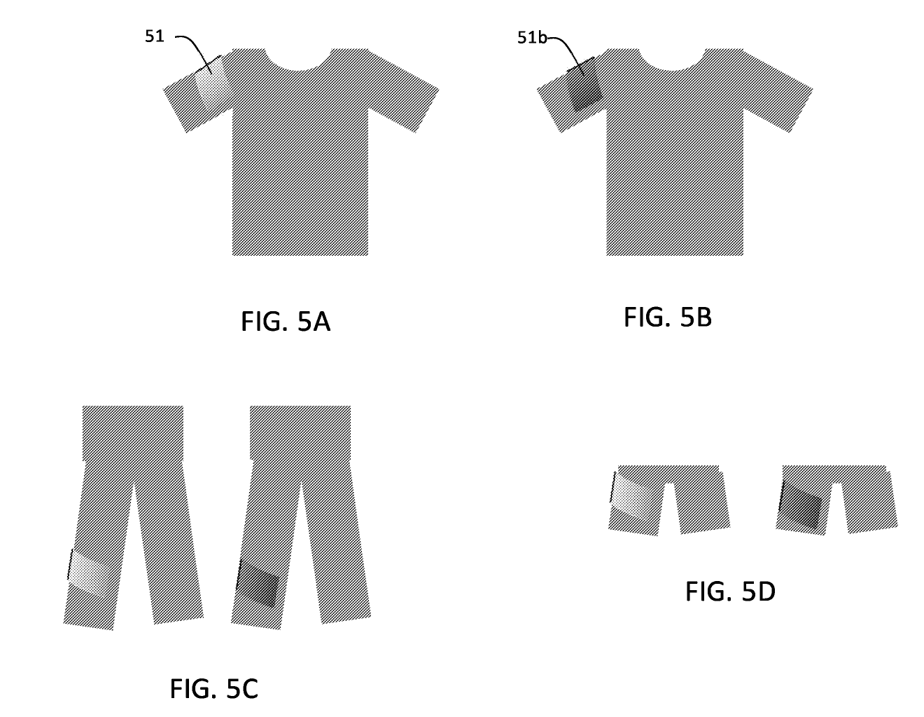

Some specific, non-limiting examples of garments include performance shirts, hoodies, and outerwear. FIGS. 5, 5A, 5B, 5C, 5D and 6 illustrate exemplary garments 50 incorporating an energy harvesting textile and having a plurality of connectors 51 operatively coupled to the textile similarly to the connectors 31 depicted in FIGS. 3A and 3B. In FIG. 6, as in FIG. 3B, several accessories 51b are shown operating from power obtained from the energy harvesting textile.

### EXAMPLE 7

### Sporting Goods, Canopies and Tents

Various items of sporting goods and gear, including for example canopies, tents, and flyes, can incorporate one or more panels of energy harvesting textile based on PE, PV and/or hybrid PE/PV fibers. Such textile panels can convert solar energy and mechanical energy (e.g., momentum transferred to the textile panel from wind and/or falling rain) to useable electrical energy. As with the footwear and garment examples described above, electrical conductors can collect and convey electrical current to a connector and/or an accessory in a manner as described above.

### EXAMPLE 8

### Luggage, Bags, and Backpacks

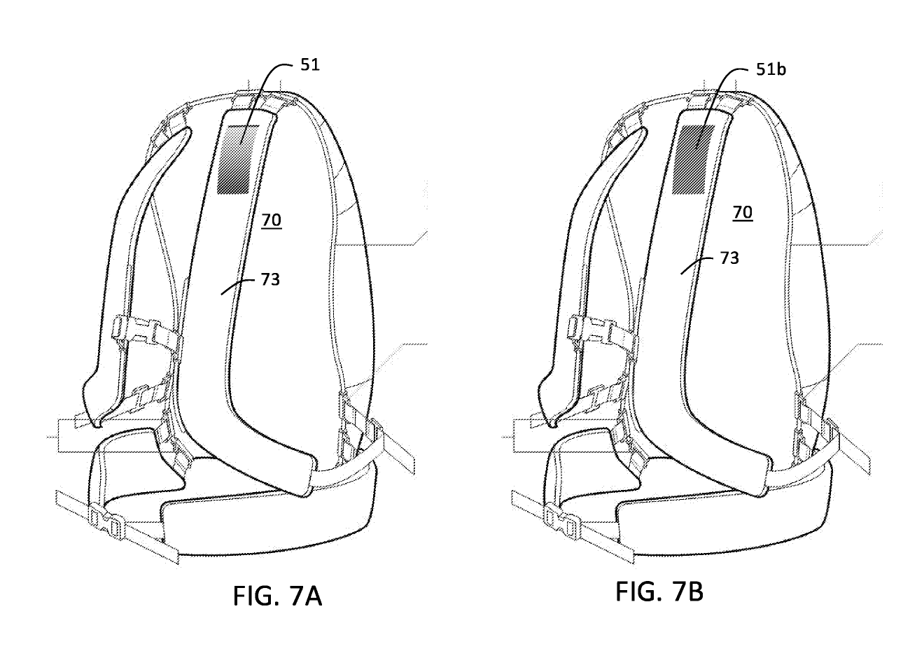

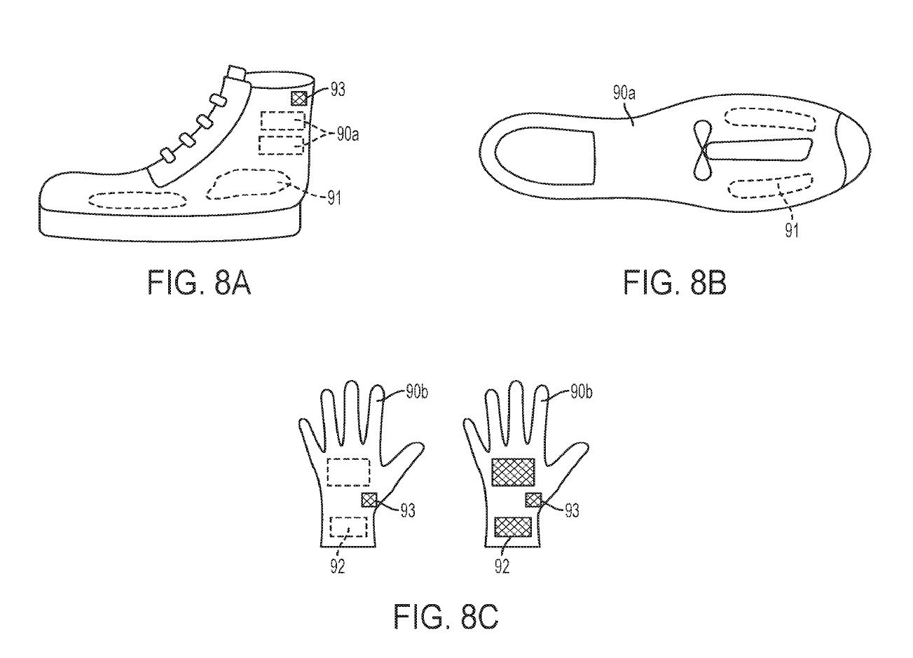

By way of reference to FIGS. 7A and 7B, various pieces of luggage, bags, and backpacks can incorporate energy harvesting textile panels based on PE, PV, and hybrid PE/PV fibers. For example, a PE/PV-based textile can encompass an entire backpack 70 to provide a continuous source of electrical power. A battery can be wirelessly charged initially, and then continuously charged via the hybrid fiber. This can be used to charge any combination of electronics wirelessly or with cables. It can also provide additional power to items incorporated into the backpack itself including but not limited to: cameras, lights, speakers, gesture control devices, etc. Some, or all, of these can be controlled via blue tooth or printed and conductive inks connected to soft circuit switches. By nature of the energy harvesters, the shoulder straps 73 can harvest energy during stretch and movement, and the spacer mesh can be inserted at the bottom of pack to harvest energy during compression of a load.

As shown in FIG. 7A, one or more electrical connectors 72 can be placed, for example, in an operative relation to a major user-contact surface, such as for example an inner surface 72a of a shoulder strap 73 or a face of the backpack 70 in contact with a user's back. Similarly, an interoperable garment 50 (FIG. 5) compatible with the backpack 70 can incorporate one or more complementarily positioned connectors 51 so as to receive power from or to deliver power to the backpack 70, enabling increased energy harvesting and storage for the combined energy platform (in this example, a backpack and a shirt).

### EXAMPLE 9

### Headwear, Mittens and Gloves

As in other examples garments and outerwear described herein, an energy harvesting textile can form one or more panels of the headwear and/or gloves, and harvested electrical current can be conveyed to connectors and/or to accessories.

### EXAMPLE 10

### Platform Accessories

Several embodiments of platform accessories are described by way of example, although many other embodiments of platform accessories will become apparent to one of ordinary skill in the art based on a review of this disclosure.

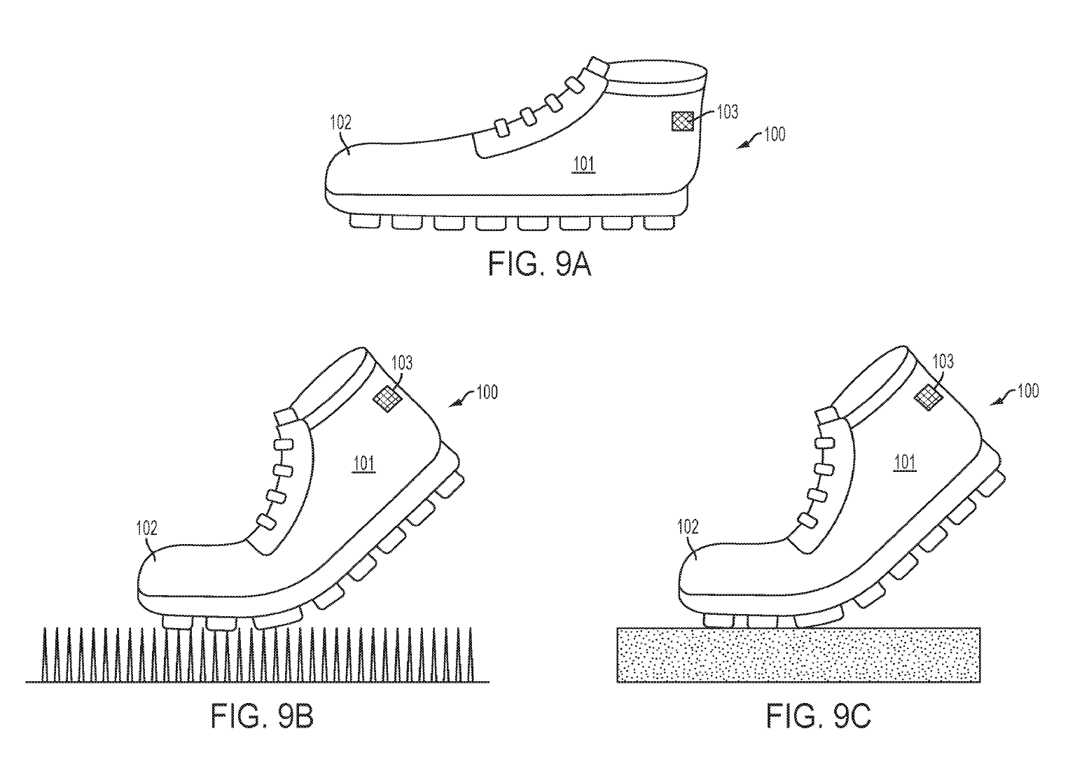

FIGS. 9A, 9B and 9C schematically illustrate several energy platform embodiments 90a, 90b incorporating a platform accessory in the form of heaters 91, 92 and a controller 93. The heaters 91, 92 can increase in temperature when a current passes therethrough from resistive heating. The heating elements 91, 92 can be formed using deposition layers, e.g., conductive, printable inks, such as graphene. Because of their natural electrical resistance, such materials rarely overheat or cause fires and can be used safely in garments and footwear and in connection with other energy harvesting platforms.

In conventional approaches for heating footwear, garments and gloves or mittens based on large amounts of insulation, the material is not air permeable or breathable, or bulky battery and wire systems are incorporated. Poor circuitry and conventional connectors can cause fires and premature failure. While such shoes can be warm, they also can be hot and clammy

Disclosed energy harvesting platforms can incorporate a controller 93, providing the ability to instantaneously regulate power to the heating elements 90a, 90b and allowing the construction of the winter boots and shoes, for example, to change From a smartphone, a user can set a suitable temperature range. A sensor can monitor temperature and the controller 93 can emit a control signal suitable for activating a heating element in response to an observed temperature falling below a selected threshold temperature. Because there can be a constant or a sustained source of energy harvested from energy platform 90a, 90b during use, continuous operation of the heating element 91, 92 and/or controller 93 can be possible. With constantly regulated heating elements, cold-weather apparel, footwear, and gear can be lighter and more flexible compared to conventional cold-weather apparel, footwear, and gear, allowing for different constructions that are more air permeable and breathable and reducing overheating and the clammy feeling that often occurs in conventional cold-weather apparel, footwear, and gear. This is easily applicable to ski boots, work boots, etc.

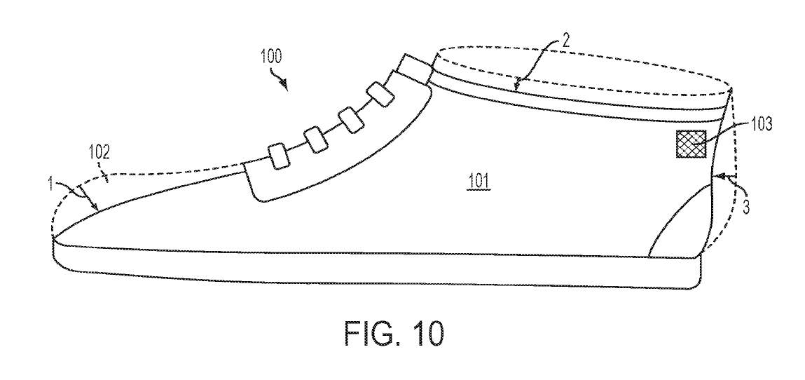

Combining energy harvesting, printed electronics, sensors, blue tooth, wireless charging, and/or battery system examples described herein can allows for many footwear modifications never before conceived. The ability to maintain a constant energy source provides an energy platform for a self-regulating strapping system 100, as depicted in FIGS. 9A, 9B, 9C and FIG. 10, for example.

As runners run long distances (high mileage and half marathons and longer) their feet often begin to swell. Conventional footwear does not respond to this swelling and often the footwear become too small for the runner's swollen foot. As the foot swells the toes can rub against an end of the toe box 102 in the item of footwear 101, causing blisters and pulling toenails off causing bleeding and wearer discomfort.

Employing one or more above-described technology examples in combination, a self-regulating strapping system can be designed into an innovative item of footwear 100. For example, from a smartphone application or other computing environment, a desired pressure of the strapping system can be set in correspondence with a selected activity, e.g., walking, hiking, running, or standing. Each selected activity can be observed using, for example, gyroscopes/gps sensors/pressure sensors (e.g., in the footwear or incorporated from the smart device) 103.

As a user increases activity the strapping system 100 can activate. A pressure sensor in the upper can continuously monitor foot swelling, or a timer can monitor a duration of an activity. Once a selected pressure or duration threshold is exceeded, the strapping system 100 can relax the compression easing the pressure on the foot. The strapping system can replace conventional shoelaces completely, be incorporated with shoelaces, or be placed in various places around the shoe upper: ankle/heal, toe box, arch. Different materials can be used for the strapping system. This can be woven or knitted as smart fibers directly into the upper and connected with different components, or sewn in separately during the construction of the upper. Smart polymers and shape memory polymers and shape memory metals can be used as strapping systems.

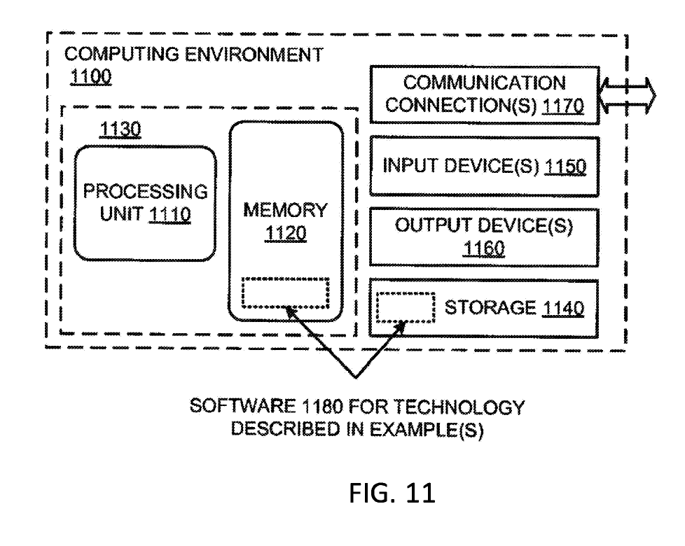

However, ideally, for use with energy harvesting and integration into this system, polymer synthetic muscles could be used. Many researchers are developing artificial muscle systems for robotic limbs. These are low cost and can be applied to open and close window shades etc. These materials can be used for a strapping system 100 as well as used to regulate temperature. If knitted or woven completely into the fabric, to open and close the intersticial spaces between fibers and yarns, causing the upper to contract or expand, as depicted by the comparison of solid and dashed lines in FIG. 11.

In the case of strapping systems, MIT, the University of Texas at Dallas, University of Wollongong (Australia) have developed different forms of artificial muscles that could be used as flexible strapping systems or as well as temperature regulation systems. Artificial muscles can expand and contract based on different stimuli: moisture, heat, electrical stimulus. These fibers can stand alone or be tubes and braided over. In the latter, at Ikeda Seichusho and Okayama University has created artificial muscles that expand and contract with air-flow in tubes that have then been braided over. If heat is necessary, then the fibers can be wrapped with conductive fiber that can use resistive heating, using a current running through the fiber, to activate the artificial muscle. These strapping systems constrict when running and loosen when standing and walking. Sensors incorporated into the shoe will sense movement (locomotion), sensors sensing impact, pressure, and foot location can additionally respond to tighten different areas of the foot.

In a similar manner of artificial muscles outlined above, cushioning systems can, and are currently, being developed that will change cushion levels on impact on surface of different hardness. For example, FIG. 10B illustrates a landing a soft turf, while FIG. 10C shows a similar foot strike on a hard surface. An outsole resilience or hardness can be adjusted according to an observed surface hardness, providing a user with a consistent feeling and degree of cushioning across various surface hardnesses. For example, sensing impact and speed can allow the footwear accessory to regulate the cushioning required. The materials can include different fabrications of the above smart artificial muscle fibers. Additionally, the outsole can be regulated in a similar manner

Other suitable accessories compatible with one or more above-described technology examples include energy storage devices such as, for example, batteries, capacitors, power sensors, altitude sickness prediction devices, secondary screens for phones, external connections to or from a given accessory, such as for example, a USB connector, lighting elements such as for example LEDs, adaptive or other smart materials incorporating, for example, desired functions or adaptable characteristics, Bluetooth or other wireless communication devices, temperature sensors, power sensors, heart rate monitors, transmitters and/or computing computing environments as described herein.

### Computing Environments

FIG. 12 illustrates a generalized example of a suitable computing environment 1100 in which described methods, embodiments, techniques, and technologies relating to, for example, controlling platform accessories, energy harvesters, etc., may be implemented. The computing environment 1100 is not intended to suggest any limitation as to scope of use or functionality of the technology, as the technology may be implemented in diverse general-purpose or special-purpose computing environments. For example, each disclosed technology may be implemented with other computer system configurations, including hand held devices, multiprocessor systems, microprocessor-based or programmable consumer electronics, network PCs, minicomputers, mainframe computers, and the like. Each disclosed technology may also be practiced in distributed computing environments where tasks are performed by remote processing devices that are linked through a communications network. In a distributed computing environment, program modules may be located in both local and remote memory storage devices.

With reference to FIG. 12, the computing environment 1100 includes at least one central processing unit 1110 and memory 1120. In FIG. 12, this most basic configuration 1130 is included within a dashed line. The central processing unit 1110 executes computer-executable instructions and may be a real or a virtual processor. In a multi-processing system, multiple processing units execute computer-executable instructions to increase processing power and as such, multiple processors can be running simultaneously. The memory 1120 may be volatile memory (e.g., registers, cache, RAM), non-volatile memory (e.g., ROM, EEPROM, flash memory, etc.), or some combination of the two. The memory 1120 stores software 1180 that can, for example, implement one or more of the innovative technologies described herein.

A computing environment may have additional features. For example, the computing environment 1100 includes storage 1140, one or more input devices 1150, one or more output devices 1160, and one or more communication connections 1170. An interconnection mechanism (not shown) such as a bus, a controller, or a network, interconnects the components of the computing environment 1100. Typically, operating system software (not shown) provides an operating environment for other software executing in the computing environment 1100, and coordinates activities of the components of the computing environment 1100.

The storage 1140 may be removable or non-removable, and includes magnetic disks, magnetic tapes or cassettes, CD-ROMs, CD-RWs, DVDs, or any other tangible medium which can be used to store information and which can be accessed within the computing environment 1100. The storage 1140 stores instructions for the software 1180, which can implement technologies described herein.

The input device(s) 1150 may be a touch input device, such as a keyboard, keypad, mouse, pen, or trackball, a voice input device, a scanning device, or another device, that provides input to the computing environment 1100. For audio, the input device(s) 1150 may be a sound card or similar device that accepts audio input in analog or digital form, or a CD-ROM reader that provides audio samples to the computing environment 1100. The output device(s) 1160 may be a display, printer, speaker, CD-writer, or another device that provides output from the computing environment 1100.

The communication connection(s) 1170 enable communication over a communication medium (e.g., a connecting network) to another computing entity. The communication medium conveys information such as computer-executable instructions, compressed graphics information, or other data in a modulated data signal. The data signal can include information pertaining to a physical parameter observed by a sensor or pertaining to a command issued by a controller, e.g., to invoke a change in an operation of a component in the system 10 (FIG. 1).

Tangible computer-readable media are any available, tangible media that can be accessed within a computing environment 1100. By way of example, and not limitation, with the computing environment 1100, computer-readable media include memory 1120, storage 1140, communication media (not shown), and combinations of any of the above. Tangible computer-readable media exclude transitory signals.

### Other Embodiments

The examples described above generally concern energy harvesting textiles and related systems and methods. Other embodiments than those described above in detail are contemplated based on the principles disclosed herein, together with any attendant changes in configurations of the respective apparatus described herein. Incorporating the principles disclosed herein, it is possible to provide a wide variety of systems adapted to convert available ambient energy to a useable form for powering any of a variety complementary electrical and/or electronic circuits, for example, sailboat sails, upholstery in automobiles, etc.

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface and the object remains the same. As used herein, “and/or” means “and” or “or”, as well as “and” and “or.” Moreover, all patent and non-patent literature cited herein is hereby incorporated by references in its entirety for all purposes.

The principles described above in connection with any particular technology example can be combined with the principles described in connection with each other technology example described herein, as will be appreciated by one of ordinary skill in the art following a review of this disclosure. Accordingly, this detailed description shall not be construed in a limiting sense, and following a review of this disclosure, those of ordinary skill in the art will appreciate the wide variety of energy harvesting and/or power-delivery platforms, and related systems incorporating disclosed accessories with such platforms, that can be devised using the various concepts described herein. Moreover, those of ordinary skill in the art will appreciate that the exemplary embodiments disclosed herein can be adapted to various other configurations and/or uses without departing from the disclosed principles.

Thus, the foregoing description of disclosed embodiments is provided to enable any person of ordinary skill in the art to make or use the disclosed innovations. Accordingly, no innovations presently claimed, or claimed in the future, are intended to be limited to the embodiments expressly shown or described herein, but are to be accorded their full scope consistent with the language of the claims, wherein reference to an element in the singular, such as by use of the article “a” or “an” is not intended to mean “one and only one” unless specifically so stated, but rather “one or more”. All structural and functional equivalents to the elements of the various embodiments described throughout the disclosure that are known or later come to be known to those of ordinary skill in the art are intended to be encompassed by the features described and claimed herein. Moreover, nothing disclosed herein is intended to be dedicated to the public regardless of whether such disclosure is explicitly recited in the claims. No claim recitation is to be construed under the provisions of 35 U.S.C. 112(f), unless the recitation is expressed using the phrase “means for” or “step for”.

Thus, in view of the many possible embodiments to which the disclosed principles can be applied, we reserve to the right to claim any and all combinations of features described herein and all that comes within the scope and spirit of the foregoing description.

1. An energy-harvesting platform, comprising:
a textile construct comprising a fiber configured to convert one or more forms of ambient energy to an electrical potential; and
an electrical connector operatively coupled to the textile construct and configured to convey the electrical potential to a complementarily configured platform accessory.

2. An energy-harvesting platform according to claim 1, wherein the textile construct comprises one or more of a woven construct, a knit construct, an entangled construct and a matted construct.

3. An energy-harvesting platform according to claim 1, wherein the textile construct comprises a spacer mesh.

4. An energy-harvesting platform according to claim 3, wherein the spacer mesh comprises opposed first and second major faces defined by respective textile panels, and wherein the fiber configured to convert one or more forms of ambient energy to an electrical potential extends from one of the textile panels to the other of the textile panels.

5. An energy-harvesting platform according to claim 1, wherein the connector comprises a deposition layer.

6. An energy-harvesting platform according to claim 1, wherein the connector comprises a near-field connector.

7. An energy-harvesting platform according to claim 1, further comprising the platform accessory.

8. An energy-harvesting platform according to claim 1, wherein the textile constructsconstruct comprises a textile panel.

9. An energy-harvesting platform according to claim 1, wherein the textile construct comprisesconstitutes a portion of an item of footwear, a garment, a sporting good, a canopy, a sail, and/or a tent.

10. An energy-harvesting platform according to claim 1, wherein the one or more forms of ambient energy comprises energy in the form of one or more of sunlight, artificial light, heat, kinetic energy, mechanical potential energy, and electromagnetic energy in a non-visible and non-infrared spectra.

11. An energy harvesting platform according to claim 10, wherein the fiber configured to convert one or more forms of ambient energy to an electrical currcntpotential is positioned and/or oriented within the textile construct in correspondence to a mode of exposure of the textile construct to the respective one or more forms of ambient energy.

12. A textile construct comprising:
a first fiber configured to convert one or more forms of ambient energy to an electrical potential;
a plurality of second fibers mechanically coupled with the first fiber to define a textile; and
an electrical connector operatively coupled to the first fiber to convey the electrical potential to a complementarily configured electrical device.

13. A textile construct according to claim 12, wherein the first fiber is woven, knit, entangled or matted with another fiber of similar or different configuration.

14. A textile construct according to claim 12, further comprising opposed first and second textile panels positioned opposite to each other, wherein the first fiber extends from the first textile panel to the second textile panel.

15. A textile construct according to claim 12, wherein the connector comprises a deposition layer.

16. A textile construct according to claim 12, further comprising a plurality of juxtaposed layers of deposited materials configured to form an electrical store.

17. A textile construct according to claim 12, wherein the first fiber is knit, woven, matted or entangled with one or more of the second fibers.

18. A textile construct according to claim 12, wherein the textile comprises a first textile, the textile construct further comprising a second textile comprising a corresponding first fiber configured to convert one or more forms of ambient energy to an electrical potential, a corresponding plurality of second fibers mechanically coupled with the first fiber; and an electrical connector configured to couple the first fiber corresponding to the second textile with the first fiber corresponding to the first textile.

19. A textile construct according to claim 12, wherein the textile constitutes a portion of an item of footwear, a garment, a sporting good, a canopy, a sail, and/or a tent.

20. A textile construct according to claim 12, wherein the plurality of second fibers comprises one or more electrically conductive fibers electrically coupled with the first fiber.
